(19) United States
(12) Patent Application Publication
(10) Pub. No.: US 2023/0180454 A1
(43) Pub. Date: Jun. 8, 2023

(54) 3D DRAM WITH SINGLE CRYSTAL ACCESS TRANSISTORS

(71) Applicant: John Bennett, Sammamish, WA (US)

(72) Inventor: John Bennett, Sammamish, WA (US)

(21) Appl. No.: 17/544,823

(22) Filed: Dec. 7, 2021

(51) Int. Cl. H01L 27/108; G11C 11/404

(52) U.S. Cl. CPC H01L 27/10805; H01L 27/10891; G11C 11/404; G11C 11/221

(57) ABSTRACT

Systems and methods are described herein for dynamic random-access memory (DRAM) memory devices. In some aspects, a memory device may be constructed in a vertical orientation such that the data-lines run perpendicular to the surface of the substrate and an arbitrary number of layers may be constructed on an area, with at least some of the layers comprising an arbitrarily high density of cells. The memory device may utilize conventional capacitor cells with a refresh function, and the other usual features of activation, sensing, write-back, and selection which are common to Dennard-cell 1T1C DRAM. In some aspects, the cells may use ferroelectric capacitor dielectric resulting in devices which hold charge indefinitely without refresh, but in most other respects operate similarly to the conventional cells.

### BACKGROUND

Modern Dynamic Random Access Memory (DRAM) and digital Logic circuits are both constructed from semiconductor devices but use different and largely incompatible processes. Logic processes continue a path of relentless yearly improvement in either speed or reduced power, while DRAM process has a much slower rate of improvement. This means that not only are the processes incompatible, but also the price and performance are drifting out of balance and there is a serious need for new memory devices that can close the gap.

The currently prevalent process for DRAM uses capacitor cells constructed as slim, tall cylinders above the logic for selection and data input/output (I/O) functions. This DRAM process is running into limits due to the need for cylinders large enough for charges to be detected by sense amplifiers after dilution of the charge over the relatively long data-line conductors which connect charge stored in the capacitors to the sense amplifiers which decide if the charge matches a zero or a one. Scaling to smaller device dimensions does not improve the resistance-capacitance load represented by the data-line, and the cylinder capacitors are nearly at the end of size reduction if they are to retain the charge needed for a 1-transistor, 1-capacitor (1T1C) Dennard memory cell composed in an array with long data-lines which diminish the signal before it reaches sense-amplifiers. The fabrication of these cylindrical capacitors is demanding and slow, accounting for much of the cost and production capacity limitation of current DRAM chips.

### BRIEF DESCRIPTION OF THE DRAWINGS

Various techniques will be described with reference to the drawings, in which:

FIGS. 1-18 illustrate example stages of a process to form a multi-layered a memory cell, in accordance with at least one embodiment;

FIG. 19 illustrates an example configuration of sense amplifiers and interface logic that can be added to a multi-layer memory cell, such as may be produced via stages of the process illustrated in FIGS. 1-18, in accordance with at least one embodiment;

FIGS. 20 and 21 illustrate the correspondence between the core elements of a single bit cell and a logical circuit diagram equivalent, in accordance with at least one embodiment;

FIG. 22 illustrates an example extension of the memory cell illustrated in FIG. 18 to form a larger area of devices, in accordance with at least one embodiment;

FIG. 23 illustrates an example configuration of sense amplifiers placed between rows of memory cells, in accordance with at least one embodiment;

FIG. 24 illustrates an example configuration of word lines of alternate decks extending to different starting points in a multi-layered memory cell, in accordance with at least one embodiment; and

FIG. 25 illustrates another example process for forming a multi-layered a memory cell, in accordance with at least one embodiment.

### DETAILED DESCRIPTION

Systems and methods are descried herein relating to Dynamic Random Access Memory (DRAM) devices, and more specifically to DRAM devices that utilize access transistors made of a unified crystal structure. The new approach introduced herein abandons vertical cylinders, using horizontal cells while accepting the inevitable smaller capacitance, and frees up some new ways to optimize memory in a 3-dimensional stack of cells. The capacitors become broader structures which can be created with thin, flat layers which may be stacked multiple cells high. The data-lines (also known as bit-lines) which move values in and out of the cells become vertical to intersect those multiple thin layers while remaining approximately 20 times shorter than their conventional horizontal form. The thin planar capacitors store less charge than the cylindrical capacitors, but the shorter data-lines function properly with that smaller charge. These flat capacitors are inexpensive to manufacture due to simple processes and many cell layers can be stacked. This layering of many layers allows superior bits per unit area than known approaches, and the simple process to form each layer results in a low cost per bit. The short data-line enables fast operations. The formation uses uniform planes of insulator, which are ideal for advanced dielectrics such as ferroelectrics. The described structure also screens cells from their neighbors, which reduces disturbance effects. The smaller cell capacitance and short data-lines enable read and write power to be minimized.

Novel insights in this device derive from identifying the opportunity to build a single crystal semiconductor data-line which is used to seed the growth of each of the semiconductor layers, allowing a region of single crystal growth extending far enough from the data-line seed to provide space for the access channel of the access transistor to be formed with single-crystal quality. The process of seeded growth of epitaxial growth has been first reported with silicon in the 1980s, but it is little used due to the difficulties of extending it over a large area. The insight in the described techniques is that only a very short distance, around 50 nanometers or less, is required to allow a single-crystal space for the access transistor, and that distance is easily exceeded. Since no other part of the memory cell requires this high-quality crystal, the 3D DRAM described herein is a uniquely suitable match to the process of repetitively extending the single crystal data-lines and then using them to seed the growth of a new layer of devices. This innovation both ensures that it is possible to choose well understood and high-quality single crystals such as silicon for the access transistors, and provides a simple process with low mask count for extending the data-line with intrinsic connection to multiple vertically stacked devices. A single layer of such devices would not be competitive in density with the current state of the art for DRAM cells, but growth is unlocked vertical to the surface of the device with low cost per cell due to the simple process utilized to form each layer, so that with enough layers both cost and density will be superior.

The heart of each individual memory cell is a planar semiconductor active core, which is formed of material from a uniformly grown layer which is then patterned to isolate cores for each device. In some cases, the layers may be annealed to optimize the crystal quality and reach of the single crystals from the data-lines where they protrude from the deck below, acting as seeds for the new layer. Beyond the access transistor, the layer may be polycrystalline or even amorphous in the region where these cores act as the center electrodes of capacitors. The cores may be doped or alloyed to be good conductors in this region, so single crystal quality is not required.

The device stacks may have large layer counts leading to high combined capacities, potentially thousands of bits per square micron. This high capacity can amortize the cost of a top or bottom layer of CMOS supporting circuits fabricated in high quality single crystal silicon. The CMOS layer being formed on top after the memory layers are formed allows the memory layers to use annealing processes which may be too hot to be compatible with logic elements. Thus, when the logic layer is added after the annealing is performed, there is extra freedom to choose the materials used in the memory cells.

There can also be cost and complexity advantages in having the CMOS support circuits built first and then building the DRAM layers above that logic and analog circuitry. In this approach, the bottom of the data-lines would be rooted in crystal contacts exposed from those underlying support circuits. The materials chosen for the memory layers may be more limited by the need to identify suitable good quality crystals and materials which can be processed at low enough temperatures to be tolerated by the underlying support circuits, but this may be outweighed by the advantage of working with a cheaper circuit-under-memory fabrication. This may be a lower cost approach avoiding the need to grow a broad single crystal layer on top, or to bond one on top with sequential stacking.

The memory devices described herein are different from other 3D memory proposals in adhering to the proven 1T-1C “Dennard cell” principles with speeds and operation which are compatible with existing industry practice. The innovation of the described techniques lies in seeing how that functionality may be maintained while finding a structure that is compatible with extension to multiple layers in the vertical direction, with simple and inexpensive fabrication. The methods described herein for 3D DRAM accepts a modest cost and complexity per layer for masking steps to obtain shapes for device elements through etching or selective deposition or implantation, while delivering functionality compatible with prior DRAM devices.

The described methods construct multiple decks substantially parallel to the surface of the substrate wafer, where each deck is a set of layers forming DRAM cells with a central core of semiconductor sandwiched below and above by dielectrics and conductors. The different parts of the semiconductor interact with these other layers to create capacitance, an access channel, and a contact to the data-line. This set of layers for a cell, which is referred to throughout this disclosure as a deck, will then be joined by more layers fabricated one over another to form a stack of multiple decks. In this realization, the active circuitry for sense amplifiers and other system functions may be placed above the multiple decks.

The processes used to realize the various elements of the memory cells may have alternatives. For example, a newly added layer may be created using negative mask followed by a deposition step to fill where the mask is absent, or by a broad deposition of material followed by a positive mask after which etching removes the unwanted deposition which is not under the mask. A preferred approach to delivering the device feature is a matter of optimization matched to the materials to be used for fillers, conductors, and semiconductors, such as using techniques that are known to those skilled in the art of semiconductor device manufacture.

The systems and techniques described herein may enable the production of memory chips which have the functions and capabilities of current DRAM but may be manufactured with higher capacity per unit area, at low cost and with good performance. Each cell is a 1-transistor 1-capacitor (1T1C) single bit memory based on the principles of the original 1T1C cell, designed by Robert Dennard in 1968, and now pervasive in the DRAM industry. The memory cells may use either an ordinary dielectric, a ferroelectric, or an anti-ferroelectric dielectric in the capacitor. Systems and methods are described herein for constructing semiconductor substrates where multiple layers of DRAM cells are simply and inexpensively fabricated such that with many layers an exceptionally high cell density is obtained which may be coupled with access circuits either below or above the DRAM cells.

Cells with ordinary dielectric will have unlimited endurance and high speed but require refresh as the capacitor charge will leak through the access transistor. The method of construction introduced here enables the growth of single crystal semiconductor, such as single crystal silicon grown by selective epitaxial overgrowth, in the access transistors at multiple layers of the device. Single crystal material enables the highest on/off ratios for minimal channel leakage and longest refresh intervals with high signal to noise ratio. Multi-layer devices may be limited to growing polycrystalline or amorphous materials with inferior performance. The method described here removes that limitation. Cells with ordinary dielectric operate with the same sequence of activation, access, sensing, reading and writing as is currently used with DRAM cells arranged in planar devices. The vertical organization of the DRAM may change speeds and power levels but is not changing the overall operation of the DRAM cells.

Cells with ferroelectric dielectric will retain charge indefinitely when operated with sufficient positive and negative voltages to reach the necessary hysteresis in the dielectric material. These devices are more tolerant of imperfect access transistors, but they still benefit from lower disturbance effects when using single crystal access devices with ideal on/off ratios. There may be some limits to the cycles of operation, requiring wear leveling methods to be added to the access path, and this complexity can be avoided if disturbance effects are low enough.

Cells with antiferroelectric dielectric have reported charge retentions of many seconds even at elevated temperature and tolerate moderate access channel performance. They do, however, require different sense amplifiers methods which could, in some cases, add size to the memory layout.

The described methods also allow the growth of single crystal layers through multiple layers of memory up to a top layer in which the single crystal growth is modified to maximize its coverage, enabling sense amplifiers and other analog or logic devices to be constructed above the memory cells. This implementation may be compared with sequential stacking to obtain a top epitaxial layer of crystal from a donor wafer. Sequential stacking may be cost justified for a single final step on a multilayer memory, if it produces a superior result.

The high capacity of the multiple DRAM levels supports the cost of the additional steps needed to integrate CMOS over the memory array, since only one final CMOS layer may have its cost shared by a large number of memory layers, such as for example, dozens of memory layers. The resulting devices enable high capacity, high-performance, general-purpose memory to be built at low cost per gigabyte and low power of operation compared to current DRAM.

The use of CMOS above the memory cells has the utility of integrating the densest general-purpose memory, DRAM, combined beneath the best of logic devices, which provides an improvement in performance and reduction in the energy needed for data access. The CMOS layers enable high quality analog and digital circuits to be incorporated with direct access to adjacent memory cells.

Other circuits built at the CMOS level may include the overall interface for the memory chip, error correction, refresh, integrity checking, sparing, and other supervisory overhead for the chip. Various forms of interface and control such as Open Memory Interface (OMI), Low Power Double Data Rate (LPDDR), Double Data Rate (DDR), Graphics Double Data Rate (GDDR), or High Bandwidth Memory (HBM) may be provided in the CMOS, and other interfaces may be implemented, which make better use of the good quality CMOS process for the control and interface logic which offers performance not matched with current processes optimized for DRAM chips.

It is also possible to add Processing In Memory (PIM) functionality to the CMOS layer, or to sequentially stack one or more additional layers on top to implement CMOS functionality which does not compete with the sense amplifiers in the first CMOS layer. This would be facilitated by substrate materials with greater heat conductivity, and in environments which can provide cooler package temperatures.

Elements in the memory layers may benefit from annealing and other high temperature processes that improve their semiconductor or dielectric quality. This is enabled by a CMOS-last order of construction where the memory stacks may be thermally processed prior to the formation of the CMOS above it, and all the materials in the memory stacks may be selected to be tolerant of the deposition, crystallization, and annealing temperature profiles encountered during the construction of the stacks, where the CMOS is not present until later.

The memory deck and CMOS top layer may use different processes but are integrated in design for a precise match in the position of connecting features. Precise alignment is possible using the optical transparency of the very thin top semiconductor and insulator combined with alignment marks in the base, so that the next levels of lithography are aligned within nanometers of the underlying memory stack. This allows true 3D integration at the limits of device geometry. A very high density and accurate placement of vias is important, which will be made possible by keeping the top layers very thin.

The memory stack does not require power and ground distribution as its devices are passively powered by sense amplifiers and other signal drivers such as the word-line drivers. Areas of the memory substrate which are not used for memory stacks, for example because the CMOS area above must be used for non-memory functions, may be patterned with structures, including capacitors or conductors or inductors, which support power and ground distribution for the CMOS functions. While off, the power loss is mostly due to the leakage of the capacitors through the access transistors. Thus, the good quality of the access transistors is essential both to the low background power drain, and to the rate of refresh.

The multiple, wide ground planes should greatly reduce disturbance effects and the short data-lines should deliver low latency with small charge transfers. This will support reliable and high-performance operation.

It may be observed that in some cases, the access gates backed by insulator may benefit from control of the back bias voltage under each gate. In this design, the gate conductor in the layer below (which, for the lowest memory layer, will be the dummy gate conductor built into the base level) act to provide the back bias. This back bias voltage may be modulated together with the voltage of the gate conductor to improve the on/off ratio of the access transistor.

Both volatile and persistent forms of memory are possible, depending on the kind of dielectric in use. The planar construction allows dielectrics of ideal uniformity in thickness and composition to be deposited by a variety of technologies including wet chemical reaction, plasma, sputtering, molecular beam, and vapor deposition schemes, including formulations modified by dopant traces or implantation. The quality of the dielectric may further be improved by annealing. The materials used will each have their ideal deposition methods and processing profile. The planar construction of the capacitors including fill materials to minimize level changes at the semiconductor edges will minimize material stress from changes in field intensity that occur around folds, generally allowing best results even with complex dielectrics.

Capacitance per cell will depend upon choice of dielectric and thickness, but values around 1 femtofarad per cell are estimated for conventional capacitor dielectrics with areal density of 100 cells per square micron per deck. This is approximately 10-fold smaller than was found in the cylindrical capacitors for 16 gigabit DRAM chips in the DDR4 generation. It should be an effective match to data-lines which may be 20 times shorter than for the horizontal data-lines of those same DDR4 devices.

The described memory devices may differ from classic 2D DRAM in having a higher ratio of sense amplifiers per memory cell. Modern DRAMs have roughly 1 sense amplifier per thousand memory cells, generally organized as 1 sense amp with 4 inputs each of which connects to roughly 256 cells. The devices described here may reach optimal performance and cost with around 64 layers, and sense amplifiers will most likely be connected to just 2 data-lines, left and right, so there may be around 8 times the density of sense amplifiers. This should not be a power problem since these amplifiers draw no power when not in use. It does however mean that these memory arrays may deliver more data bits per activation than an equivalent count of memory cells in a 2D DRAM. Conversely, that means that a smaller number of cells need to be activated to obtain the same data transfer size, which should further reduce power consumption. It also has implications for error correction strategy for sparing, and for data bit serialization organization.

In one aspect, a memory device may be constructed to include a plurality of one-transistor, one-capacitor memory cells forming a stacked structure of multiple decks which are parallel to a substrate of the memory device. Individual decks of the multiple decks may each include a capacitive element formed of a conductive center electrode separated by a dielectric insulator from a second electrode, with the second electrode formed of a pair of ground planes positioned above and below the core electrode, the capacitive element being substantially planar; and an access transistor controlling current flow to the capacitive element, with the access transistor including an access channel that is in communication with the center electrode. The memory device may additionally include at least one data-line oriented substantially orthogonal to at least one of the multiple decks, where the at least one data-line is in communication with capacitive elements of the plurality of memory cells through access channels of individual memory cells of the plurality of memory cells and operable to store and access charge, representing data, in the capacitive elements of the plurality of memory cells. The at least one data-line may be formed of a singular conductive crystal grown to extend through the multiple decks making contacts to the access channels of individual memory cells of the plurality of memory cells.

In another aspect, a memory device may include a plurality of one-transistor, one-capacitor memory cells forming a stacked structure having multiple layers. Individual memory cells of the plurality of memory cells may each include a capacitive element formed of a conductive center electrode separated by a dielectric insulator from a second electrode, the capacitive element being substantially planar; and a column of conductive single crystal forming a data line positioned orthogonal to the planar capacitive element. The column of conductive single crystal may extend outward into a planar channel of an access transistor that is coupled to the conductive center electrode of the capacitive element, with the access transistor and the data line controlling access to and storage of charge, representing data, in the capacitive element, the column of conductive single crystal and the planar channel formed of the single crystal. In some cases, multiple columns of conductive single crystal forming the data lines of the individual memory cells may be aligned to form a memory device data line that is substantially orthogonal to the individual memory cells.

In yet another aspect, a method of forming a memory device may include a number of steps, such that are implemented to form a single deck of one-transistor, one capacitor memory cells that form a stacked structure of multiple decks. The steps may include etching at least one opening through an insulator layer to a planar crystal base layer positioned below the insulator layer; forming a single-crystal structure up through the at least one opening and extending a distance outward from the opening on the insulating layer to form at least one access channel of an access transistor coupled to a capacitive element; and forming and treating a crystal structure over substantially the remainder of the insulator layer to form a substantially planar new crystal base layer. The single-crystal structures through the at least one opening of the multiple decks may form data lines to access and store charge in the capacitive elements of the multiple decks.

The figures, as described below, illustrate the desired elements which may be obtained using a choice of process known to those skilled in the art of semiconductor fabrication. Throughout these illustrations, it should be understood that the layers may be deposited by successive methods of vapor, molecular beam, sputtering, liquid chemistry, electroplating, oxidation, plasma, ion implantation, or other deposition methods, or combinations of these techniques, used in the semiconductor industry, as may be suitable for fabrication of these materials. Etching and removal may be done by evaporation, solvents, acids, reactive plasma, chemically enhanced plasma, and other removal methods used in the semiconductor industry. The methods used for depositing or removing materials at each step may be optimized by persons skilled in these standard processes for semiconductor manufacture. It should be appreciated that relative size and shapes of the different components of the illustrated memory cell are only given by way of illustrative example, and that various other relative sizes and shapes of the various components are contemplated herein.

The figures illustrate steps in forming one small patch or area of devices, sufficient to convey the important device features. In practice, thousands of these patches will typically be arrayed over the surface of a chip, with many chips arrayed across a semiconductor wafer to create a useable device. These patches may be fabricated in unison and the operations shown here would typically occur in parallel over the entire wafer, as is standard practice in semiconductor chip fabrication. At some stages there may be etching steps which cut between the patches and fill with insulator, resulting in properly isolated devices.

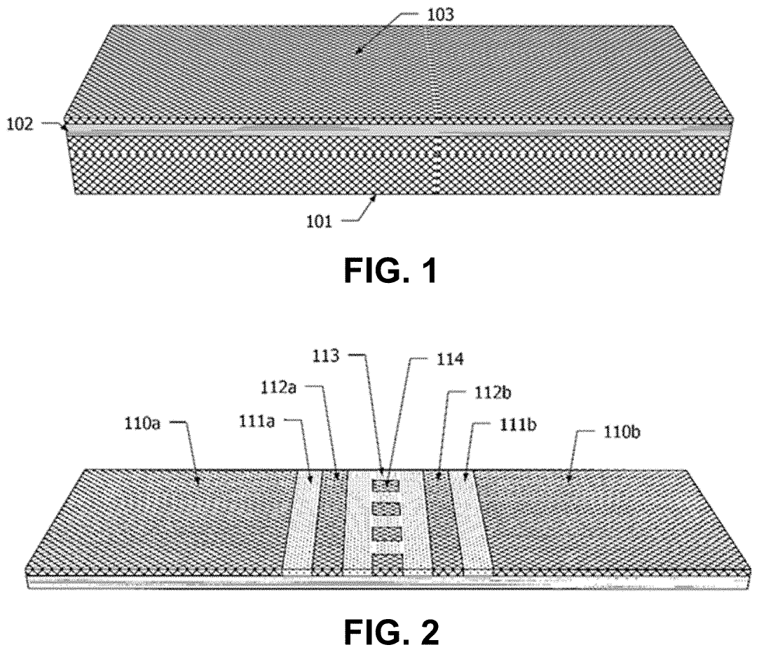

FIGS. 1-18 illustrate example stages of a process to form a multi-layered a memory cell. FIG. 1 illustrates a first step in preparing the semiconductor substrate. This begins with an insulating layer (102) implanted into a crystalline base (101), isolating the base from a single-crystal semiconductor epitaxial layer (103). The crystal orientation may be chosen to optimize device characteristics, while the insulating layer may be created using implantation of ions such as oxygen or nitrogen which combine with the substrate to create insulation, and annealing upon a wafer surface, as is one usual method of preparing a Semiconductor On Insulator (SOI) wafer. The epitaxial layer will be doped to be conductive by default, for example with silicon it may be N-doped with moderate amounts of phosphorous or arsenic. This may be intrinsic to the base wafer, or it may be added after the insulation layer has been implanted.

FIG. 2 illustrates that regions of the epitaxy have been converted to or replaced with an insulator material. There will be cells formed in a mirror symmetry left and right. The capacitor area of the cells will be above the epitaxial regions (110a, 110b) which will become ground planes. Bands of insulator (111a, 111b) separate the epitaxial regions (110a, 110b) from the access gate underlays (112a, 112b), which will provide body bias for the gates to be formed above. Moats of insulator (113) isolate seed islands (114) which will be the base of crystal growth for the data-lines to be formed above, each data-line being shared by a left and right memory cell. Insulator 113 may surround seed islands 114 within a plane of a layer of the illustrated memory cell. The seed islands 114 may take any of a variety of shapes, such as square, circular, rectangular, oval, or various other symmetric and nonsymmetric shapes. It should be understood that the elements of this base do not form memory cells. This base supports crystal growth and back bias for memory cells which will come in the decks above.

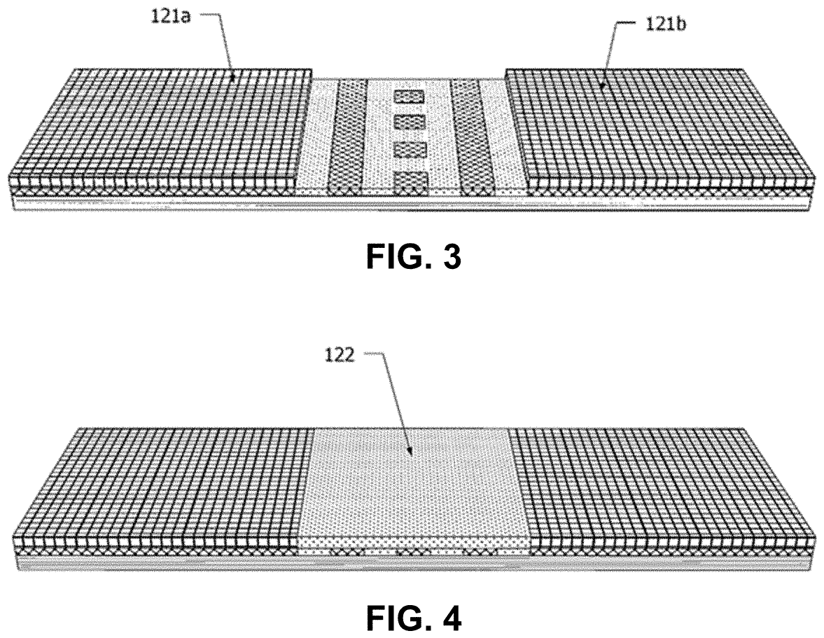

FIG. 3 illustrates the addition of conductive ground planes (121a, 121b) which will be the underside ground electrodes for the capacitor areas of the first layer of memory cells. As illustrated the conductive ground planes (121a, 121b) may be formed above the epitaxial regions (110a, 110b), and substantially or totally cover the epitaxial regions (110a, 110b), having similar or the same shape and dimensions.

FIG. 4 illustrates the addition of an insulator fill (122) over the central elements (e.g., central third of the rectangular memory device) up to a level roughly level with the conductive ground plane.

FIG. 5 illustrates the deposition of the access-gate dielectric (131) over the roughly level combined surface of the insulator fill and ground planes (e.g., over most or all of the top-most surface of the memory device). This dielectric will form the lower side of the cell capacitors. The dielectric may consist of one or more layers chosen to provide compatible interfaces to the ground plane below and the semiconductor core above, and to provide the desirable properties of resistance to breakdown, dielectric constant, and optional properties such as ferroelectric or anti-ferroelectric behavior.

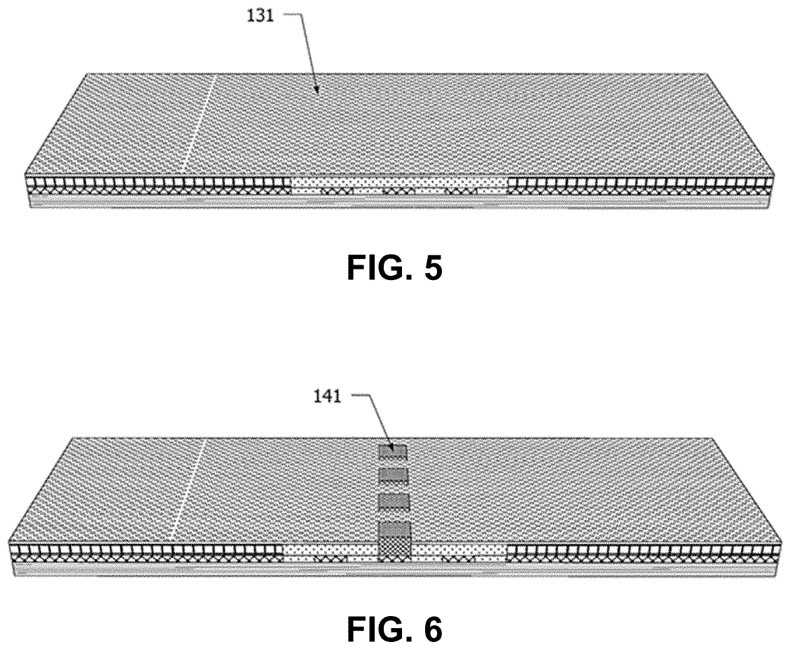

FIG. 6 illustrates that via holes are etched down through dielectric layer (131) to reach the crystal islands (114) of the base level and then crystal data-lines (141) have been grown up from the islands until they reach above the level of the dielectric layer (131). These pillars are doped to be normally conductive and may be annealed to heal their crystal structure before the next step begins. The vias holes may have a square cross section as illustrated, or may have various different cross-sectional shapes. There may also be overall density advantages to lengthening the bridge sections between left and right cells so that the data-line vias may be offset on alternate lines to allow for closer cell spacing while allowing for limits to how small the via holes can be or how close they can be to each other.

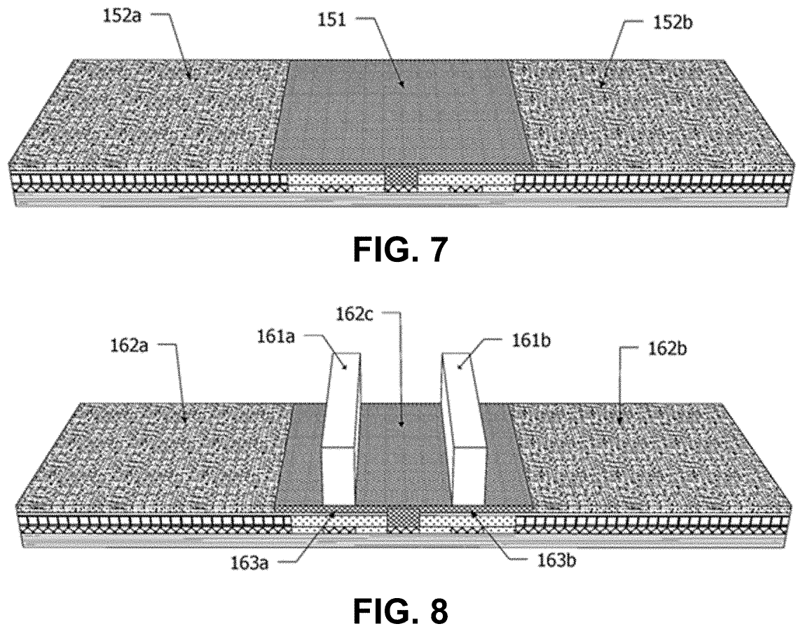

FIG. 7 shows the growth of semiconductor layer (151, 152a, 152b) over the dielectric layer (131), possibly including a buffer layer above the dielectric to promote good crystal growth. In the central region (151) (e.g., a portion of the area of the memory device), the crystal data-lines act as seeds to influence orderly single crystal growth, but at some distance away the semiconductor (152a,152b) may be either polycrystalline or amorphous as the seeding effect of the data-line pillars has limited reach. The doping for this semiconductor layer should be depleted or otherwise favor non-conductive state to form low leakage access channels. A planarization step may occur to create a level surface eliminating irregularities due to the seed crystal islands and accumulated level changes and edges from underlying steps.

FIG. 8 illustrates the use of masks (161a, 161b) shielding the locations where the access channels (163a, 163b) will be formed. In some cases, masks (161a, 161b) may extend across a width of the memory device within the central region (151) and extend upwards to shield the locations where the access channels (163a, 163b) will be formed. The rest of the semiconductor surface may be implanted or alloyed to make it conductive by default, so that the capacitor cores (162a, 162b) and the data-line connections (162c) will be conductive during device operation.

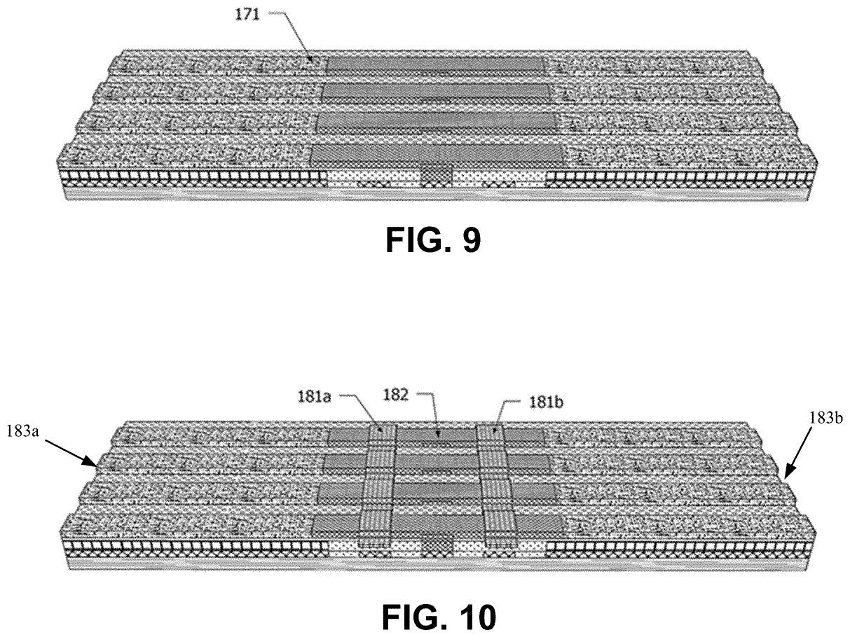

FIG. 9 illustrates the etching of the semiconductor layer (151, 152a, 152b) to reveal the linear cores (171) of semiconductor which will be central to the memory cells, each core supporting 2 memory cells in reflected symmetry, left and right. In the example illustrated, the linear cores (171) may form rectangles aligned with the orientation of the memory device, separated from each other by a distance. The pattern shown may be part of a larger area where the left and right edges join to other devices at their right and left edges. Those connections will be cut at some convenient etching stage later in the process to ensure isolation from neighbors.

FIG. 10 illustrates left and right gate dielectric (181a, 181b) deposited over the region of the linear cores (171), which will be the access transistors connecting the data-lines and central cores (182) to the capacitor areas (183a, 183b). The gate dielectric (181a, 181b) may be laid down in a linear pattern orthogonal to the cores. As those skilled in creating the patterns for device lithography will know, the linear patterns used for the cores, the gates, and other steps are among the easiest patterns to create at fine resolutions. However, it should be appreciated that other patterns may be utilized for some or all of the described processes and components, to optimize various attributes of the resulting memory device and/or to provide certain advantages in the manufacturing process.

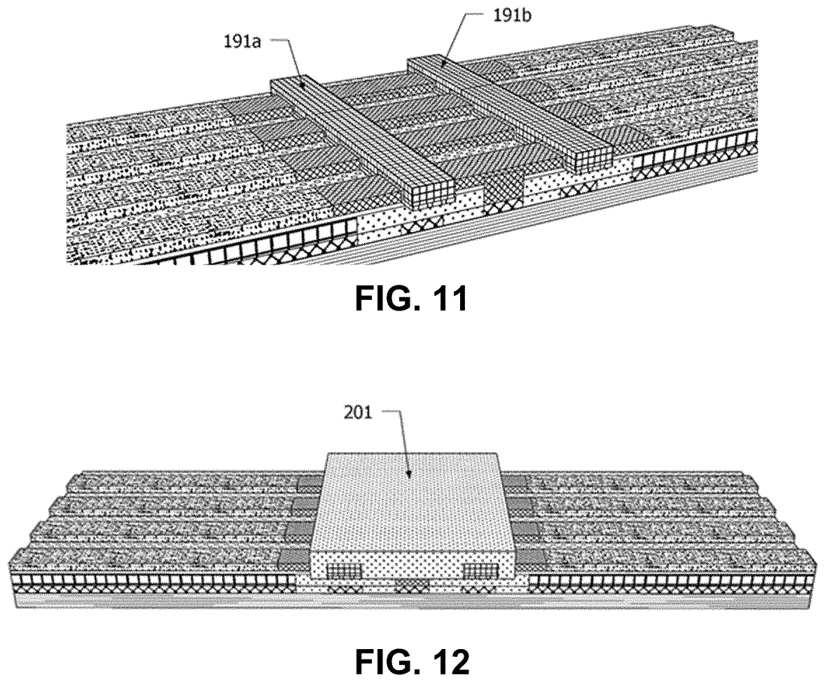

FIG. 11 illustrates addition of left and right gate conductor (191a, 191b) over top of the gate dielectric (181a, 181b), which in some realizations will be a self-aligned process using the same mask for both gate dielectric and gate conductor. These conductors (191a, 191b) are the word-lines in the memory array. One word-line is changed to an active voltage to open the access transistors on one layer while the other decks of memory all remain in the off state with the access transistors closed. Within the active layer, only one of the word-lines is active, so in these illustrations the left cells may be active while the right word-line remains off, or the right word-line may be active while the left remains off. In this way each data-line, connecting vertically through the decks, is connected only to one cell at a time. All the other decks and the other side of the active deck remain isolated with their access transistors off. This is how the device reads or writes just one memory cell per data-line per activation. As each gate conductor is connected running across multiple access channels in adjacent memory cells, and each of those access transistors connects to a different data-line, this connected gate conductor functions as a word-line which activates multiple cells so that a multi-bit word of data is read or written onto the same number of data-lines, one per cell, so the data is read or written in parallel words. The number of bits in the word will depend upon how long the word-line is, which is a number that will vary in different chips but is expected to range up to hundreds of cells crossed with each continuous gate conductor.

FIG. 12 illustrates the addition of a layer of insulator fill (201) over the central elements, including the gates (181a, 181b) and central conductor cores (191a, 191b). This insulator isolates the central elements. In some cases, the layer of insulator fill (201) may partially or completely overlap the central portion of semiconductor layer (151).

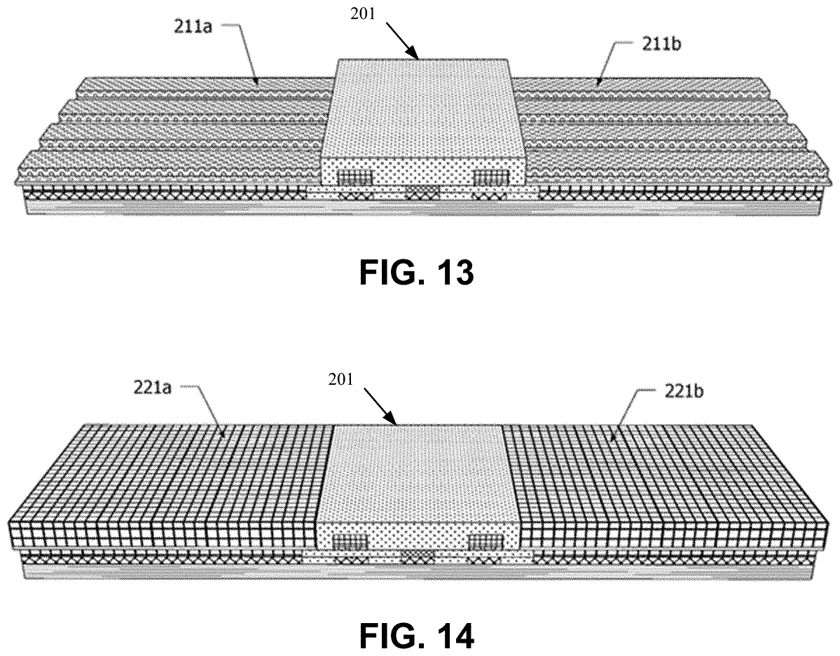

FIG. 13 illustrates the deposition of left and right capacitor dielectric (211a, 211b) over top of the semiconductor cores (171) in the capacitor region of the memory cells. The dielectric may consist of one or more layers chosen to provide compatible interfaces to the ground plane above and the semiconductor core (171) below, and to provide the desirable properties of resistance to breakdown, dielectric constant, and optional properties such as ferroelectric or anti-ferroelectric behavior.

FIG. 14 illustrates the deposition of left and right ground plane conductors (221a, 221b) for the capacitor region (e.g., above and partially or substantially overlapping (110a, 110b) and (121a, 121b)) of the memory cells. The ground plane conductor materials should be chosen for a balance of conductivity, ease of fabrication, and surface compatibility with the capacitor dielectric material. After the ground plane conductor is deposited there should be an approximately level surface from the combination of ground planes and central insulator fill (201).

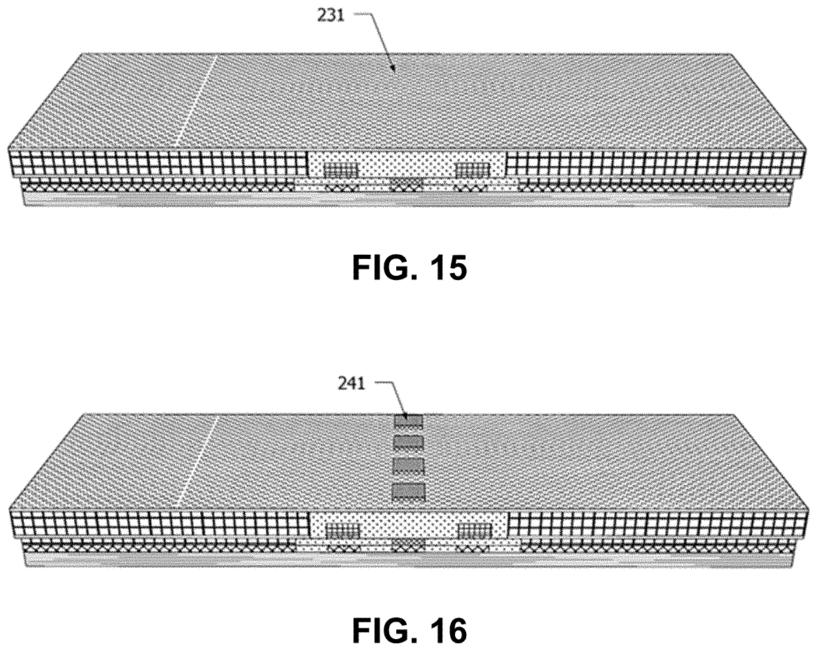

FIG. 15 illustrates the broad uniform deposition of capacitor dielectric (231) similar to and overlapping at least in part the area occupied by layer (131) described in reference to FIG. 5. In some cases, dielectric layer 231 may be multilayer in composition.

FIG. 16 illustrates that via holes are etched down, through dielectric layer (231) to reach the crystal islands (114) of the base level, and then crystal data-lines (241) have been grown up from the islands (114) until they reach above the level of the dielectric layer (231). Crystal data-lines (241) may take the form of pillars or other shaped extensions above dielectric layer 231. In some cases, crystal data-lines (241) are doped to be normally conductive and may be annealed to heal their crystal structure before the next step begins. The first deck of memory cells is now complete FIG. 16 is the next deck up equivalent of FIG. 6. Repeating the operations which create the elements described in FIGS. 7-16 will create a new deck, and this cycle may be repeated many times to create many decks stacked vertically.

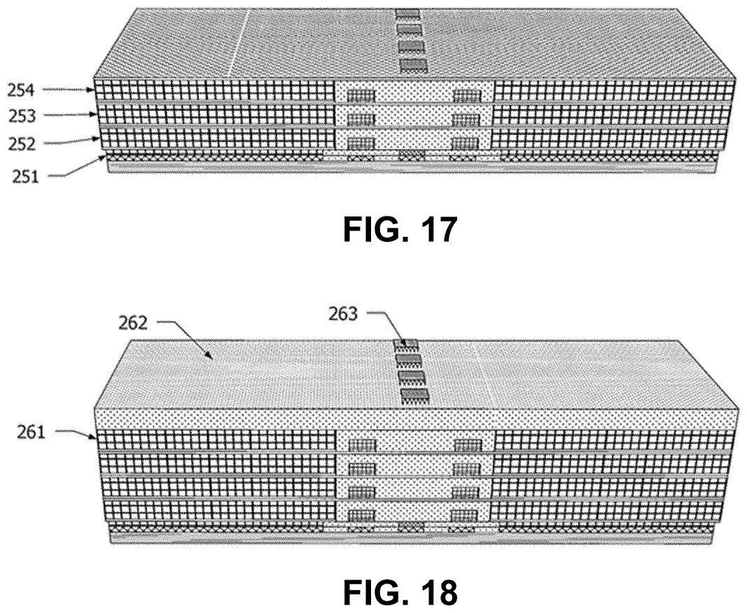

FIG. 17 shows the state of the DRAM construction when 3 cycles are complete, with 3 decks (252, 253, 254) of memory cell built on top of the base layer (251) which supports the first memory deck with its underlying ground plane, gate back bias, and seed crystal for the data-lines.

FIG. 18 illustrates the addition of a final memory deck (261) onto the memory device illustrated in FIG. 17 and shows that it is topped with a protective insulator fill (262) instead of a capacitor dielectric, while the data-lines will use deeper via holes and taller crystal growth to extend the data-lines (263) above the final surface. At this point the memory cell stack is complete and ready for sense amplifiers and other interface logic to be connected above.

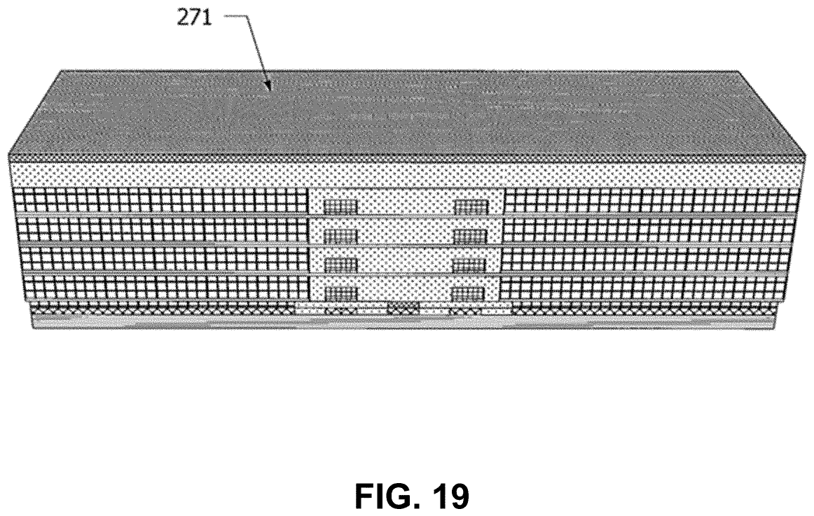

FIG. 19 illustrates one way the sense amplifiers and interface logic can be added to a memory device, such as the memory device illustrated in FIG. 18, by using carefully controlled crystal growth from the data-line seeds with annealing to create a broad single crystal (271). The surface insulator may also be designed with a surface layer to promote crystallization, which was also an option for the central section of the dielectric layers further down. This broad single crystal may then be used as the substrate for constructing sense amplifiers and other analog or logical devices.

An alternative approach ends the construction at the step illustrated in FIG. 16 and then adds the top single crystal semiconductor layer by sequential stacking, a process where a donor wafer is flipped on top of the memory stacks, bonded directly, and then the thin epitaxial crystal is cleaved from the donor and planarized to leave the high-quality top crystal (271). Again, the sense amplifiers and other devices are fabricated in that top crystal layer. Note that this is different to face to face bonding of finished wafers. Here the top level is a blank donation, devices will be formed after it is bonded, cleaned, and planarized. The lithography and device formation is aligned using transparency of the ultra-thin top layer to use alignment marks visible lower down. The data-lines may be contacted and extended up into the top layer by normal vias on a micron depth scale.

The sense amplifiers will fill the area above the cell stack and provide connection to every data-line via. The sense amplifier design should be narrow so that it will fit in the same space as a pair of adjacent planar cells from the stack, so the sense amps take up the same area as the underlying cells. Other arrangements may have fewer sense amps and some form of multiplexing to select from more than 2 data-lines per sense amp.

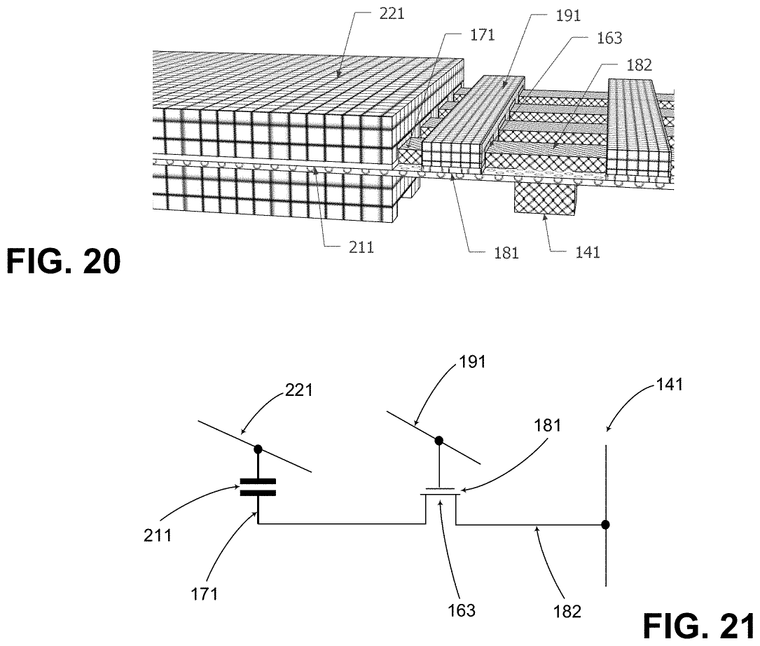

FIGS. 20 and 21 illustrate the correspondence between the core elements of a single bit cell and the logical circuit diagram equivalent. The data-line (141) forms a contact with the conductive bridge in the middle (bridge) of the semiconductor core. The access channel (163) underneath a gate dielectric (181) and gate conductor (191) form an access transistor which controls the flow of current to and from the data-line (141). The access channel (163) connects to the semiconductor core (171) which is one electrode of the storage capacitor, at the center of the capacitor. The dielectric (211) is above and below the electrode forming the interior of the capacitor. The other electrode of the storage capacitor is the ground plane conductor (221) which is also both above and below, with the ground plane below shared with the deck or base below.

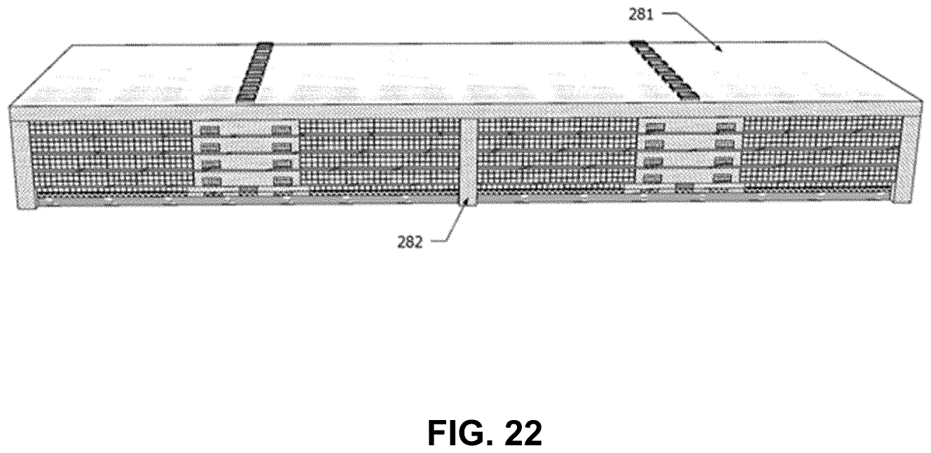

FIG. 22 illustrates an example memory device that includes multiple memory stacks, such as the memory stack of FIG. 18, repeated adjacent to one another to form a larger area of devices (281), with the stacks separated by insulating fill (282) in trenches to ensure the capacitors for different cells are isolated from adjacent stacks. As illustrated, the areas of insulating fill (282) may run the width of the memory device and may extend partially or completely through the memory device in the vertical direction, to isolate capacitors from different adjacent cells. As also illustrated, the insulating fill portion (282) may not extend through the top layer, which may include a CMOS layer or other layer that contains control logic, etc.

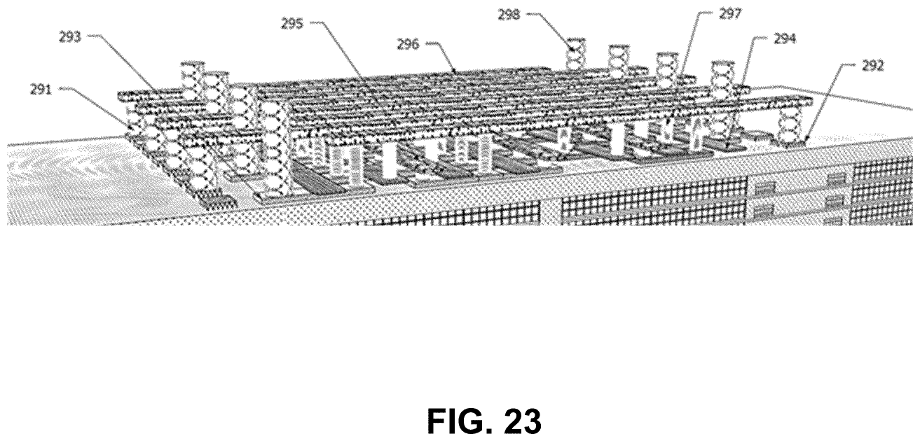

FIG. 23 illustrates how sense amplifiers may be placed between rows of cells. In this realization, a sense amplifier is connected (291) to a first data line and connected (292) to a second data line, only one of which is active while the other serves as a passive reference as is standard practice for DRAM sense amplifiers. Each bit-line is connected to a conducting rail (296) The transistor channels (293) formed from the top silicon layer (271) work with conductive layers (294, 295) through dielectrics and vias (297) to form the circuit of the sense amplifiers, and the outputs of the sense amplifier will appear as a complementary pair on vias (298) which also form the path through which data flows in reverse to write a value through the sense amplifier into a memory cell, in the usual method for DRAM.

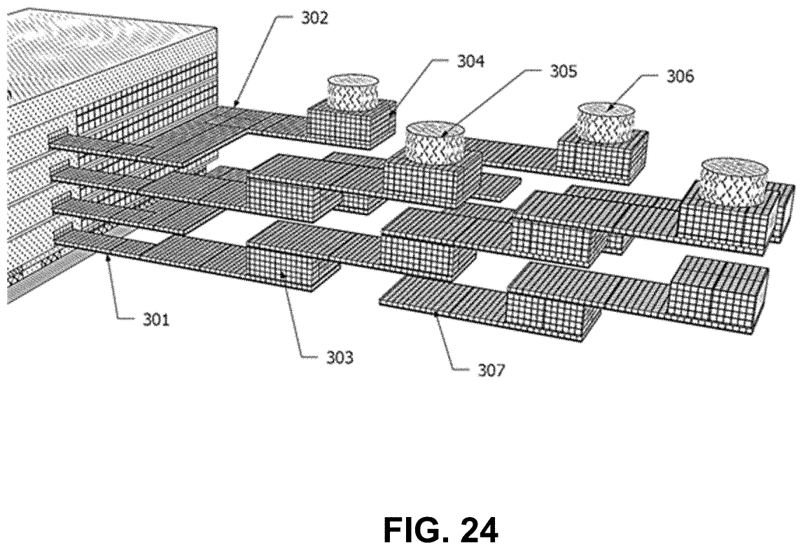

FIG. 24 illustrates an example of how the word lines of alternate decks may extend (301, 302) to different starting points, and then alternating masks create offset vertical conductors (303, 304) eventually leading to offset vias (305, 306) at the top. Using just 2 sets of masks for this implementation. there are some orphaned structures (307) at the lower levels which do not function or interfere with any function. The alternative method of stair-step formation by shrinking masks, used for example in NAND formation, may be a cheaper process but may generate steps occupying more area.

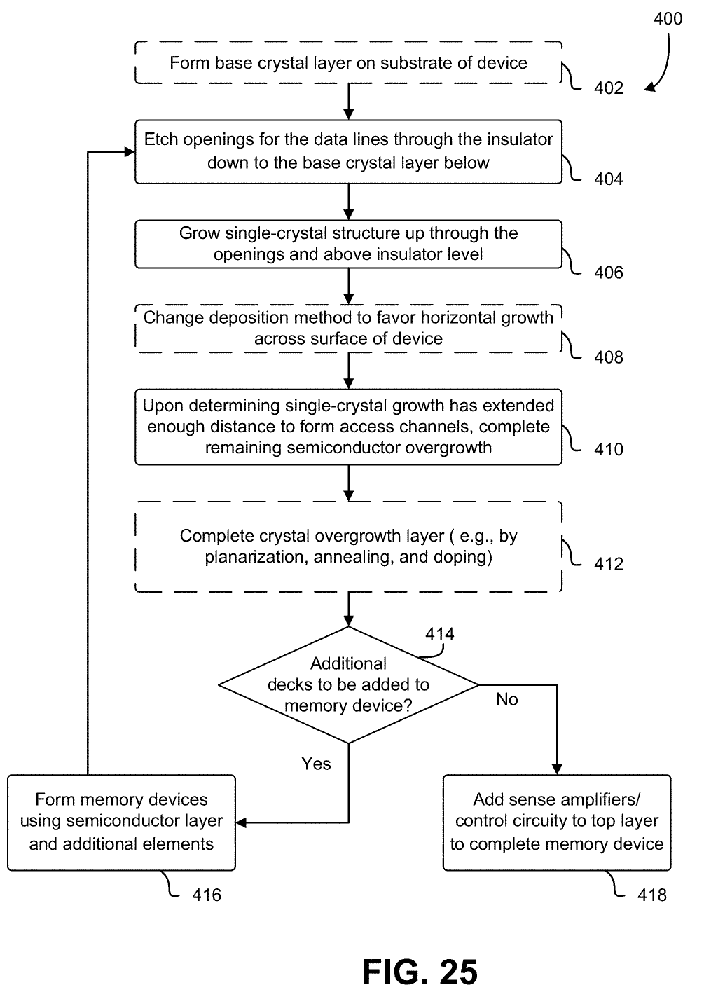

FIG. 25 illustrates an example process 400 for forming a memory cell, such as a memory cell that includes some or all of the features and/or process steps described above in reference to FIGS. 1-18, 19, 23-25, and/or incorporates the circuit layout described in reference to FIGS. 20 and 21. As illustrated and described in reference to FIG. 25, dashed lines may indicate optional, but not required steps or operations in process 400, such that process 400 may be performed with or without these optional operations.

Process 400 may begin, optionally, at operation 402, where a base crystal layer of the memory device may be formed, such as on a substrate or chip that is selected based on the desired size of the memory device. Next, at operation 404, openings for the bit/data lines may be etched through the insulator down to the base crystal layer below (e.g., the initial layer formed on the substrate). Next, at operation 406, crystal may be grown or formed up through the openings, using a method which preferentially grows upon the exposed crystal but does not deposit on the insulator surface. The crystal growth may include doping so that the bit/data lines in the openings are conductive. In some cases, the crystal growth may include forming a single-crystal structure that extends a distance outward from the opening on the insulating layer to form at least one access channel of an access transistor coupled to a capacitive element, which will store charge representing a value in individual memory cells.

When the growth is sufficient that the crystal is grown through the openings and above the insulator level, optionally, the deposition method may be changed to favor horizontal growth across the surface, at operation 408. Operations 406 and 408 may be performed using epitaxial crystal overgrowth techniques. In some cases, forming the single-crystal structure up through the at least one opening, of operation 406, is performed using a first deposition method, and forming the single-crystal structure extending the distance outward from the opening on the insulating layer to form the at least one access channel is performed using a second deposition method. In some cases, the first deposition method may include doping.

When it is determined that the single crystal growth has extended sideways or horizontally far enough to include the placement of the access channels, the remaining semiconductor overgrowth may be completed to form a cover of the underlying layer, at operation 410. In some cases, optionally, the crystal overgrowth layer may now be finished by steps such as planarization, annealing, and doping, at operation 412.

Process 400 may proceed to operation 414, where it may be determined if more layers are to be added to the memory device. If yes, process 400 may proceed to operation 416, in which the memory devices or cells may be formed using a semiconductor layer and additional elements. In some cases, operation 416 may include connecting data lines, formed by the vertical portions of the single-crystal structure, to the rest of the memory deck, to enable accessing the capacitive elements coupled to the access channels of access transistors formed by the single-crystal structures. In some cases, operation 416 may include forming a new base crystal layer upon which another memory device deck may be built. In some cases, forming and/or treating the crystal structure over substantially the remainder of the insulator layer to form the substantially planar new crystal base layer, at operations 410, 412, and/or 416 may include forming a second crystal structure over substantially the remainder of the insulator layer that is different from the single-crystal structure that formed the access channels and filled the openings (e.g., is not single-crystal or is multi-crystal in structure).

Upon completion of operation 416, process 400 may then proceed to loop back through operation 404-414, until no more layers are to be formed on the device. At this point, when no more layers are to be formed, process 400 may proceed to operation 418, in which sense amplifiers and/or other control or interface circuitry or components may be added to the top layer of the device, such as via processes described in greater detail above. In some aspects, upon determining that no more memory layers will be added to the device, then operation 408 may be replaced with an exit which finishes the top of the stack of decks with structures such as sense amplifiers which connect to the crystal bit lines that have grown through the final level of openings.

As described herein, the technique of extending the data/bit lines using repeated epitaxial crystal overgrowth (ECO) provides simple and quality device construction using silicon or similar crystalline semiconductors. While ECO processes have bene around since the 1980's, they have generally not been particularly useful because the area of horizontal single crystal growth was much smaller than needed for devices of that era, when channels were still micron length and they were looking to build complex circuits. Given the geometry of the described memory cells, channels can be reduced to around 20 nm long—and a memory cell needs just one—ECO can be beneficially employed to aid in forming a cost effective and competitively dense memory cell device.

It should be appreciated the process 400 is only given by way of example, and that various features and/or steps described above in reference to FIGS. 1-24 may be combined with process 400, such as forming the capacitive element for each deck, etc. Steps described above in reference to FIGS. 1-19, and 22-24 may be combined or added into process 400 and/or individual operations thereof.

In some aspects, the described system and techniques may include one or more of the following features. It should be appreciated that various combinations of these features are completed herein, and that language indicating inclusion of a combination of features is not a requirement that those features operation in combination to provide one or more advantages as described herein.

1. In one aspect, a deck of one-transistor, one-capacitor (1T1C) memory cells are constructed with elements formed from alternating layers of conductor, dielectric insulation, and semiconductor, so that the devices shall be substantially planar and thin, where some of the layers are uniformly deposited and some other layers contain shaped elements, where data storage capacitance for the cells shall be formed with one conductive element which is shaped to be the center electrode separated by a dielectric insulator from the other electrode formed of a pair of ground planes above and below the core electrode, where the access transistors controlling current flow in and out of the capacitor are formed where gate electrodes and gate insulator shaped to cross multiple adjacent memory cells in the same deck form access transistors, where multiple decks are constructed above each other providing multiple layers of memory cell, where the data-lines which move the charges to and from the cells run vertically between decks and are etched and filled with conductive crystal grown to run vertically through the decks making contacts to the access channels in each deck.

2. The elements of (1) where the crystal growth of the data-line vertically provides seeds to form a single crystal horizontal plane in the next deck which extends far enough from the data-line seeds to provide single crystal semiconductor for the channels of the access transistors.

3. The elements of (1) where the data-lines terminate with the memory cells in connections with sense amplifiers formed in an additional layer of single crystal silicon.

4. The elements of (3) where the additional layer of single crystal is grown from the seeds provided by vertical extension of the data-lines.

5. The elements of (3) where the additional layer of single crystal is provided by sequential stacking of an epitaxial layer cleaved from a donor wafer.

6. The elements of (1) where the ground planes and word line conductor of a lower layer provide the back bias voltage for correct operation of the semiconductor devices in an adjacent upper layer.

7. The elements of (1) where the capacitor dielectrics support ferroelectric operation where charge is stored with the assistance of ferroelectric properties of the dielectric.

8. The elements of (1) where the capacitor dielectrics support anti-ferroelectric operation where charge is stored with the assistance of anti-ferroelectric properties of the dielectric.

9. The elements of (1) where all materials in the multiple stacks of memory are chosen for their mutual compatibility in surfaces and their ability to sustain annealing or other thermal processes used to optimize the crystal, electrical, and storage properties of the memory decks.

10. In one aspect, a deck of one-transistor, one-capacitor (1T1C) memory cells are constructed with elements formed from alternating layers of conductor, dielectric insulation, and semiconductor, where a central element for each memory cell is a pillar of conductive single crystal, where the crystal pillars are extended by the height of one deck at a time, pausing to grow a horizontal region of single crystal suitable for the formation of high quality access transistors, where the capacitors for the memory cells are formed on the same horizontal deck connecting to the other side of the access transistors, while in between these elements horizontal layers of conductive ground plane and capacitor dielectric are grown, resulting in a cycle of layers which creates multiple layers of memory cells connected to the vertically grown columns of crystal data lines.

11. The elements of (10) where a set of adjacent access transistors on each deck and on the same side of the data-line pillar shall have a continuously connected gate electrode so as to form a word line which switches that line of access transistors on or off in concerted action.

12. The elements of (10) where the ground planes for adjacent capacitors are joined together to form a shared ground plane.

13. The elements of (11) where each word line is activated separately from other word lines in the stack of decks, as well as separately from the word line on the opposite side of a shared data line column.

14. The elements of (12) where all the ground planes in the multiple decks may be connected together to form a larger stable reference voltage and capacitor reserve to reduce noise levels when individual cells are charged or discharged.

19. The elements of (18), where additional analog or switching functions for computation or processing may be included within the CMOS layer beside the sense amplifiers and control circuits or bonded or deposited in one or more additional CMOS layers above.

Embodiments of this disclosure are described herein, including the best mode known to the inventors for carrying out the described techniques. Variations of those embodiments may become apparent to those of ordinary skill in the art upon reading the foregoing description. The inventors expect skilled artisans to employ such variations as appropriate, and the inventors intend for embodiments of the present disclosure to be practiced otherwise than as specifically described herein. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated herein or otherwise clearly contradicted by context.

All references including publications, patent applications, and patents cited herein are hereby incorporated by reference to the same extent as if each reference were individually and specifically indicated to be incorporated by reference and were set forth in its entirety herein.

What is claimed is:

1. A memory device comprising:
a plurality of one-transistor, one-capacitor memory cells forming a stacked structure of multiple decks which are parallel to a substrate of the memory device, individual decks of the multiple decks comprising:
a capacitive element formed of a conductive center electrode separated by a dielectric insulator from a second electrode, the second electrode formed of a pair of ground planes positioned above and below the core electrode, the capacitive element being substantially planar; and
an access transistor controlling current flow to the capacitive element, the access transistor comprising an access channel that is in communication with the center electrode; and
at least one data-line oriented substantially orthogonal to at least one of the multiple decks, the at least one data-line in communication with capacitive elements of the plurality of memory cells through access channels of individual memory cells of the plurality of memory cells and operable to store and access charge, representing data, in the capacitive elements of the plurality of memory cells,
wherein the at least one data-line is formed of a singular conductive crystal grown to extend through the multiple decks making contacts to the access channels of individual memory cells of the plurality of memory cells.

2. The memory device of claim 1, wherein the crystal growth of the at least one data-line provides seeds to form a single crystal horizontal plane in a subsequent deck of the multiple decks, wherein the single crystal horizontal plane extends from the data-line seeds to provide single crystal semiconductor for the access channel in the subsequent deck.

3. The memory device of claim 1, wherein the at least one data-line is in communication with a sense amplifier positioned near a periphery of the stacked structure.

4. The memory device of claim 3, wherein the sense amplifier is formed in an additional layer of single crystal silicon.

5. The memory device of claim 4, wherein the additional layer of single crystal silicon is grown from the seeds provided by vertical extension of the at least one data-line.

6. The memory device of claim 4, wherein the additional layer of single crystal silicon is provided by sequential stacking of an epitaxial layer cleaved from a donor wafer.

7. The memory device of claim 1, wherein the pair of ground planes and word-line conductors of a lower deck within the multiple decks provide a back bias voltage for correct operation of the capacitive element and the access transistor of an upper deck within the multiple decks.

8. The memory device of claim 1, wherein the dielectric insulator comprises ferroelectric properties.

9. The memory device of claim 1, wherein the dielectric insulator comprises anti-ferroelectric properties.

10. A memory device comprising:
a plurality of one-transistor, one-capacitor memory cells forming a stacked structure having multiple layers, individual memory cells of the plurality of memory cells comprising:
a capacitive element formed of a conductive center electrode separated by a dielectric insulator from a second electrode, the capacitive element being substantially planar; and
a column of conductive single crystal forming a data line positioned orthogonal to the planar capacitive element, the column of conductive single crystal extending outward into a planar channel of an access transistor that is coupled to the conductive center electrode of the capacitive element, the access transistor and the data line controlling access to and storage of charge, representing data, in the capacitive element, the column of conductive single crystal and the planar channel formed of the single crystal; and
wherein multiple columns of conductive single crystal forming the data lines of the individual memory cells are aligned to form a memory device data line that is substantially orthogonal to the individual memory cells.

11. The memory device of claim 10, wherein the memory device data line is formed of a unitary crystal structure.

12. The memory device of claim 11, wherein the unitary crystal structure is formed incrementally to allow an access channel of the access transistor to extend towards the capacitive element of individual memory cells of the plurality of memory cells.

13. The memory device of claim 10, wherein individual layers of the multiple layers of the stacked structure comprise:
a plurality of capacitive elements; and
a plurality of access transistors, wherein the plurality of access transistors are located centrally among the plurality of capacitive elements.

14. The memory device of claim 13, wherein the plurality of access transistors comprise a common gate electrode that forms a word line, wherein the word line controls operation of the plurality of access transistors collectively.

15. The memory device of claim 14, wherein at least one individual layer of the multiple layers of the stacked structure comprises at least two word lines, wherein the at least two word lines are independently controlled.

16. The memory device of claim 10, wherein the second electrode is formed of a pair of ground planes positioned above and below the core electrode.

17. The memory device of claim 16, where ground planes of capacitive elements of adjacent memory cells of the plurality of memory cells are joined together to form a shared ground plane.

18. The memory device of claim 17, wherein the shared ground plane forms a stable reference voltage to reduce noise levels when individual memory cells are charged or discharged.

19. The memory device of claim 10, further comprising at least one control device formed in or by a complementary metal-oxide-semiconductor (CMOS) layer positioned above the plurality of memory cells.

20. A method of forming a memory device, comprising:
for each deck of one-transistor, one capacitor memory cells that form a stacked structure of multiple decks:
etching at least one opening through an insulator layer to a planar crystal base layer positioned below the insulator layer;
forming a single-crystal structure up through the at least one opening and extending a distance outward from the opening on the insulating layer to form at least one access channel of an access transistor coupled to a capacitive element; and
forming and treating a crystal structure over substantially the remainder of the insulator layer to form a substantially planar new crystal base layer,
wherein the single-crystal structures through the at least one opening of the multiple decks form data lines to access and store charge in the capacitive elements of the multiple decks.

21. The method of claim 20, wherein growing the single crystal structure up through the at least one opening and extending the distance outward from the opening on the insulating layer to form the at least one access channel is performed using epitaxial crystal overgrowth.

22. The method of claim 20, forming the single-crystal structure up through the at least one opening is performed using a first deposition method, and wherein forming the single-crystal structure extending the distance outward from the opening on the insulating layer to form the at least one access channel is performed using a second deposition method.

23. The method of claim 22, wherein the first deposition method comprising doping.

24. The method of claim 20, wherein forming and treating the crystal structure over substantially the remainder of the insulator layer to form the substantially planar new crystal base layer compromises forming a second crystal structure over substantially the remainder of the insulator layer.

25. The method of claim 24, wherein the second crystal structure is multi-crystal structure.

26. The method of claim 20, wherein treating the crystal structure over substantially the remainder of the insulator layer to form the substantially planar new crystal base layer comprises at least one of planarization, annealing, or doping.

27. The method of claim 20, further comprising forming a top layer of the memory device, the top layer comprising at least one sense amplifier in communication with the data lines.
